(19) United States
(12) Patent Application Publication
(10) Pub. No.: US 2026/0371496 A1
(43) Pub. Date: Nov. 19, 2026

(54) METHOD OF MANUFACTURING PRINTED WIRING BOARD AND PRINTED WIRING BOARD

(71) Applicant: MEKTEC CORPORATION, Tokyo (JP)

(72) Inventors: Kaita KOSHIDA, Tokyo (JP); Kenta CHOKKI, Tokyo (JP); Tomohiko YOSHIDA, Tokyo (JP); Tomoya ICHIBANGASE, Tokyo (JP)

(21) Appl. No.: 19/741,702

(22) Filed: Jul. 14, 2026

Related U.S. Application Data
(63) Continuation of application No. PCT/JP2026/005712, filed on Feb. 17, 2026.

(30) Foreign Application Priority Data
Mar. 3, 2025 (JP) 2025-033257

(51) Int. Cl. H05K 3/24; H05K 1/03; H05K 3/42

(52) U.S. Cl. CPC H05K 3/24; H05K 1/0393; H05K 3/42; H05K 2201/032; H05K 2203/03

(57) ABSTRACT

A method of manufacturing a printed wiring board according to an embodiment includes preparing a double-sided aluminum foil-clad substrate, forming a through-hole that penetrates the double-sided aluminum foil-clad substrate in a thickness direction or a bottomed hole with a bottom portion in which an aluminum foil is exposed, performing a zincate treatment on an aluminum foil and the aluminum foil, plating the aluminum foils and having undergone the zincate treatment to form a barrier plating layer, performing a conductive treatment on the through-hole or the bottomed hole, and plating the through-hole or the bottomed hole having undergone the conductive treatment to form a plating layer that electrically connects the aluminum foil and the aluminum foil.

### CROSS-REFERENCE TO RELATED APPLICATIONS

This is a bypass continuation of International PCT Application No. PCT/JP2026/005712, filed on Feb. 17, 2026, which claims priority to Japanese Patent Application No. 2025-033257, filed on Mar. 3, 2025, which are incorporated by reference herein in their entirety.

### TECHNICAL FIELD

The present invention relates to a method of manufacturing a printed wiring board and, more specifically, relates to a method of manufacturing a printed wiring board including an interlayer connection path that electrically connects aluminum foils insulated by an insulating base material.

### BACKGROUND ART

In recent years, printed wiring boards using double-sided aluminum foil-clad laminates in which aluminum foil, rather than copper foil, is bonded to both sides of an insulating base material (hereinafter, also referred to as “aluminum-based printed wiring boards”) have been under consideration. Although aluminum is less conductive than copper, it is less expensive and lighter than copper. Therefore, for example, using an aluminum-based printed wiring board in a wiring harness of vehicles such as electric vehicles is expected to help reduce vehicle weight and contribute toward lower CO₂ emissions.

Interlayer connection paths such as plated through-holes are formed in printed wiring boards. When fabricating an aluminum-based printed wiring board, through-holes are punched into a double-sided aluminum foil-clad laminate by punching using a die. In doing so, the aluminum foils are electrically connected to each other by deforming the aluminum foils so that the aluminum foils on the front and back of the insulating base material come into physical contact with each other.

### SUMMARY

However, interlayer connection paths formed by punching have weak connection strength and low connection reliability. In particular, in the case of flexible printed wiring boards, bending of the printed wiring boards can compromise the electrical connections provided by the interlayer connection paths.

In addition, with punching, it is difficult to control the position and size (diameter) of the formed through-holes with high precision. Drilling and laser machining enable the position and size of through-holes to be controlled with high precision. However, with these methods, it is difficult to bring the aluminum foils on the front and back of the insulating base material into physical contact with each other.

In addition, even when through-holes formed by drilling or laser machining are subjected to a conductive treatment and then plated as in the case of forming plated through-holes in conventional copper clad laminates, it is difficult to ensure good adhesion between the aluminum foils and the plating layer due to an oxide film that naturally forms on the surface of the aluminum foils.

The present invention has been made based on the technical insights described above, and an object thereof is to provide a method of manufacturing a printed wiring board that enables an aluminum-based printed wiring board including highly reliable interlayer connection paths to be obtained and to provide the printed wiring board. However, the present invention is not limited to this object, and an object corresponding to each effect produced by a configuration of each embodiment to be described later may also be regarded as an object of the present invention.

A method of manufacturing a printed wiring board according to an aspect of the present invention includes preparing a double-sided aluminum foil-clad substrate including an insulating base material, a first aluminum foil provided on a first main side of the insulating base material, and a second aluminum foil provided on a second main side of the insulating base material, forming a through-hole that penetrates the double-sided aluminum foil-clad substrate in a thickness direction or a bottomed hole with a bottom portion in which the second aluminum foil is exposed, performing a zincate treatment on the first aluminum foil and the second aluminum foil, plating the first aluminum foil and the second aluminum foil having undergone the zincate treatment to form a barrier plating layer, after forming the barrier plating layer, performing a conductive treatment on the through-hole or the bottomed hole, and plating the through-hole or the bottomed hole having undergone the conductive treatment to form a plating layer that electrically connects the first aluminum foil and the second aluminum foil.

In addition, in the method of manufacturing a printed wiring board described above, the barrier plating layer and/or the plating layer may be made of nickel or tin.

In addition, in the method of manufacturing a printed wiring board described above, the barrier plating layer and/or the plating layer may be made of copper.

In addition, in the method of manufacturing a printed wiring board described above, the plating may be button plating, and the method may further include removing the barrier plating layer from portions of the first aluminum foil and the second aluminum foil that are not covered by the plating layer, and patterning the first aluminum foil and/or the second aluminum foil from which the barrier plating layer has been removed.

In addition, in the method of manufacturing a printed wiring board described above, the plating may be button plating, and the method may further include patterning the first aluminum foil and/or the second aluminum foil that are not covered by the plating layer but are covered by the barrier plating layer.

In addition, in the method of manufacturing a printed wiring board described above, the plating may be panel plating, and the method may further include patterning the first aluminum foil and/or the second aluminum foil that are covered by the plating layer and the barrier plating layer.

In addition, in the method of manufacturing a printed wiring board described above, the plating may be electrolytic copper plating or electroless copper plating.

In addition, in the method of manufacturing a printed wiring board described above, the aluminum foils may be made of pure aluminum or an aluminum alloy.

In addition, in the method of manufacturing a printed wiring board described above, the double-sided aluminum foil-clad substrate may be flexible.

A printed wiring board according to an aspect of the present invention includes an insulating base material, a first wiring pattern provided on an upper side of the insulating base material, the first wiring pattern including a first aluminum foil between the insulating base material and the first wiring pattern, a second wiring pattern provided on a lower side of the insulating base material, the second wiring pattern including a second aluminum foil between the insulating base material and the second wiring pattern, and a plating layer formed on an inner wall of a through-hole of the insulating base material to electrically connect the first wiring pattern and the second wiring pattern, wherein a barrier plating layer is provided between the plating layer and the first aluminum foil and between the plating layer and the second aluminum foil, and a zinc film is present between the barrier plating layer and the first aluminum foil and between the barrier plating layer and the second aluminum foil.

In addition, in the printed wiring board described above, the barrier plating layer and/or the plating layer may be made of nickel or tin.

In addition, in the printed wiring board described above, the barrier plating layer and/or the plating layer may be made of copper.

In addition, in the printed wiring board described above, the first and second aluminum foils may be made of pure aluminum or an aluminum alloy.

In addition, in the printed wiring board described above, the insulating base material may be flexible.

According to the present invention, a method of manufacturing a printed wiring board that enables an aluminum-based printed wiring board including highly reliable interlayer connection paths to be obtained and the printed wiring board can be provided.

### BRIEF DESCRIPTION OF DRAWINGS

FIG. 1 is a flowchart for illustrating an example of a method of manufacturing a printed wiring board according to a first embodiment.

FIG. 2A is a process sectional view for illustrating an example of the method of manufacturing a printed wiring board according to the first embodiment.

FIG. 2B is a process sectional view for illustrating the example of the method of manufacturing a printed wiring board according to the first embodiment, continuing from FIG. 2A.

FIG. 2C is a process sectional view for illustrating the example of the method of manufacturing a printed wiring board according to the first embodiment, continuing from FIG. 2B.

FIG. 3 is a sectional view for illustrating Modification 1 of the first embodiment.

FIG. 4 is a sectional view for illustrating Modification 2 of the first embodiment.

FIG. 5A is an example of photographs showing a cross section of a plated through-hole in a printed wiring board according to Embodiment 1.

FIG. 5B is an example of photographs showing a cross section of a plated through-hole in a printed wiring board according to Embodiment 2.

FIG. 5C is an example of photographs showing a cross section of a plated through-hole in the printed wiring board according to Embodiment 2 after a hot oil test.

FIG. 5D is an example of photographs showing a cross section of a plated through-hole in a printed wiring board according to Embodiment 3.

FIG. 5E is an example of photographs showing a cross section of a plated through-hole in the printed wiring board according to Embodiment 3 after a hot oil test.

FIG. 6 is a flowchart for illustrating an example of a method of manufacturing a printed wiring board according to a second embodiment.

FIG. 7A is a process sectional view for illustrating an example of the method of manufacturing a printed wiring board according to the second embodiment.

FIG. 7B is a process sectional view for illustrating the example of the method of manufacturing a printed wiring board according to the second embodiment, continuing from FIG. 7A.

### DETAILED DESCRIPTION

Hereinafter, embodiments of the present invention will be described with reference to the drawings. Note that in each drawing, a same reference sign is attached to elements with the same configuration or function. In addition, the drawings are schematic in nature and are intended to mainly show characteristic portions of each embodiment, and the relationship between thickness and planar dimensions, the ratio of the thicknesses of respective layers, and the like differ from those in reality.

### First Embodiment

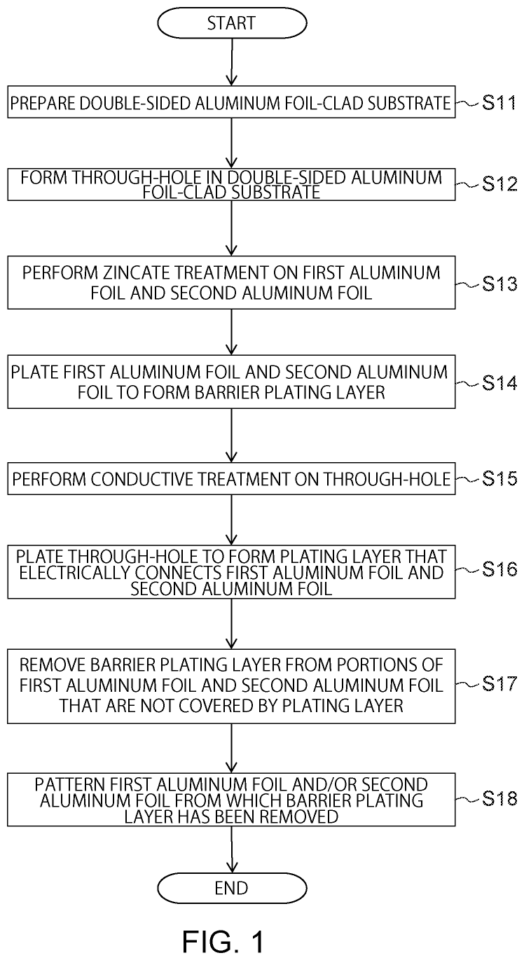

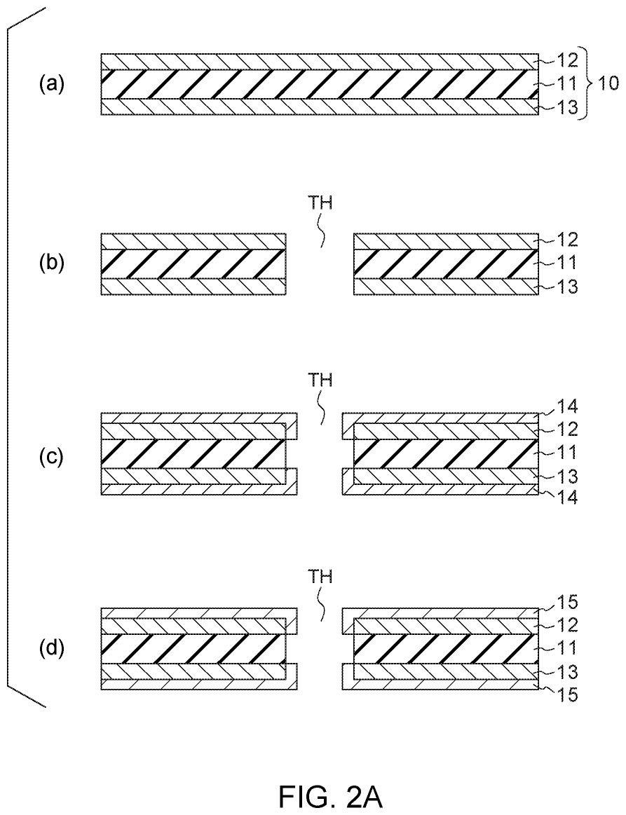

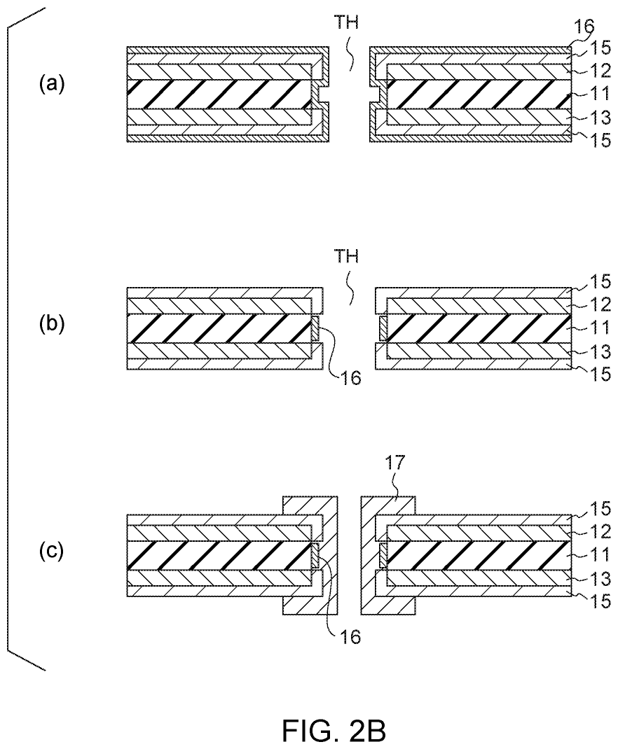

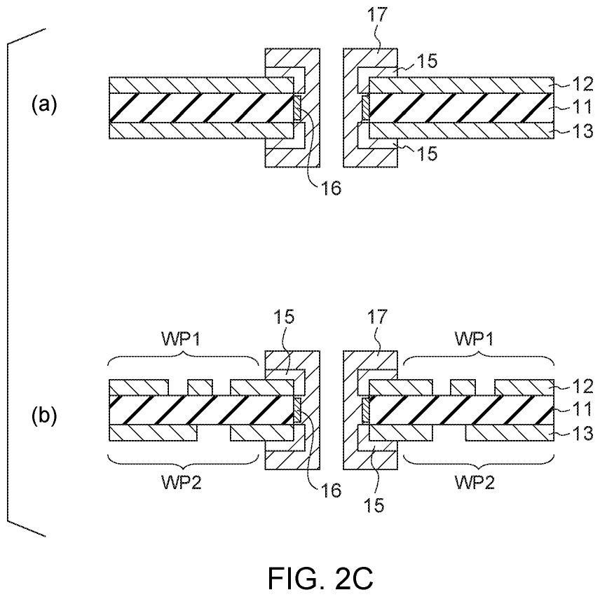

A method of manufacturing a printed wiring board according to a first embodiment will be described with reference to the flow chart in FIG. 1 and the process sectional views in FIGS. 2A to 2C.

Step S11: As shown in FIG. 2A (a), a double-sided aluminum foil-clad substrate 10 is prepared. The double-sided aluminum foil-clad substrate 10 includes an insulating base material 11 with an upper side (first main side) and a lower side (second main side), an aluminum foil 12 provided on the upper side of the insulating base material 11, and an aluminum foil 13 provided on the lower side of the insulating base material 11. The double-sided aluminum foil-clad substrate 10 is, for example, an aluminum foil-clad laminate (aluminum clad laminate: ACL). In the present embodiment, the double-sided aluminum foil-clad substrate 10 (insulating base material 11) is flexible.

Note that the material of the insulating base material 11 is not particularly limited, and while the material is, for example, polyimide (PI), the material may be other insulating materials such as liquid crystal polymer (LCP) or polyethylene terephthalate (PET). In addition, the insulating base material 11 may be a plurality of insulating films bonded together with an adhesive. Furthermore, an inner conductive layer (wiring layer) may be provided inside the insulating base material 11. In addition, the insulating base material 11 may be a rigid material such as glass-epoxy resin or ceramic.

The aluminum foils 12 and 13 may be made of an aluminum alloy or pure aluminum. In the case of an aluminum alloy, for example, aluminum alloys containing 99% or more aluminum (such as those in the JIS 1000 series) are applicable.

Step S12: As shown in FIG. 2A (b), a through-hole TH is formed in the double-sided aluminum foil-clad substrate 10. The through-hole TH penetrates the double-sided aluminum foil-clad substrate 10 in a thickness direction. The through-hole TH may be formed by drilling or by laser machining using a CO₂ laser or the like. Note that after forming the through-hole TH, desmearing that removes smear may be performed.

Step S13: A zincate treatment is performed on the aluminum foil 12 and the aluminum foil 13. Due to the zincate treatment in the present step, as shown in FIG. 2A (c), an oxide film on the surfaces of the aluminum foils 12 and 13 is removed and a zinc film 14 is formed. The zinc film 14 is formed on the surfaces of the aluminum foils 12 and 13. A thickness of the zinc film 14 ranges from several nanometers to several tens of nanometers.

Step S14: As shown in FIG. 2A (d), the aluminum foils 12 and 13 having undergone the zincate treatment are plated to form a barrier plating layer 15. The barrier plating layer 15 is formed on the surfaces of the aluminum foils 12 and 13. The plating in the present step is, for example, copper plating, in which case the copper plating may be either electrolytic copper plating or electroless copper plating. Although not illustrated in FIG. 2A (d), the zinc film 14 thinly remains between the aluminum foil 12 and the barrier plating layer 15 (between the aluminum foil 13 and the barrier plating layer 15).

Step S15: A conductive treatment is performed on the through-hole TH. The conductive treatment of the present step is similar to the conductive treatment performed on through-holes formed in conventional double-sided copper clad laminates. Specifically, first, as shown in FIG. 2B (a), by immersing the double-sided aluminum foil-clad substrate 10 in a suspension in which carbon particles (carbon black powder, fine graphite) are uniformly dispersed in a solvent, a conductive carbon layer 16 is formed over the entire surface of the double-sided aluminum foil-clad substrate 10. The conductive carbon layer 16 is formed by physical adsorption of carbon particles onto the surface of the double-sided aluminum foil-clad substrate 10 and has a thickness ranging from several nanometers to several tens of nanometers. Next, as shown in FIG. 2B (b), the conductive carbon layer 16 is removed, with the exception of the conductive carbon layer 16 on the insulating base material exposed on an inner wall of the through-hole TH. Note that in the present step, a conductive layer may be formed using conductive materials other than conductive carbon (such as conductive pastes or conductive polymers).

Step S16: As shown in FIG. 2B (c), the through-hole TH having undergone the conductive treatment is plated to form a plating layer 17. The plating layer 17 serves as an interlayer connection path (plated through-hole) that electrically connects the aluminum foil 12 and the aluminum foil 13. While the plating layer 17 is, for example, copper plating, the plating layer 17 may also be nickel plating or the like.

In the present example, the plating layer 17 is selectively formed only in and around the through-hole TH by button plating. Specifically, after forming a mask with an opening at and around the through-hole TH using a dry film or the like, plating is performed.

Step S17: As shown in FIG. 2C (a), the barrier plating layer 15 in portions of the aluminum foil 12 and the aluminum foil 13 that are not covered by the plating layer 17 is removed by etching.

Step S18: the aluminum foil 12 and/or the aluminum foil 13 from which the barrier plating layer 15 has been removed is patterned. In the present example, as shown in FIG. 2C (b), a wiring pattern WP1 is formed by patterning the aluminum foil 12 and a wiring pattern WP2 is formed by patterning the aluminum foil 13. Note that only one of the aluminum foil 12 and the aluminum foil 13 may be patterned. In addition, after the present step, portions of the wiring patterns WP1 and WP2 to serve as terminals may be gold-plated.

According to the method of manufacturing a printed wiring board described above, a printed wiring board is obtained in which wiring patterns provided on both sides of the insulating base material and including an aluminum foil are electrically connected to one another via interlayer connection paths formed in through-holes.

### Advantageous Effects

As described above, in the method of manufacturing a printed wiring board according to the first embodiment, after forming the through-hole TH in the double-sided aluminum foil-clad substrate 10, a zincate treatment is performed to remove the oxide film on the surfaces of the aluminum foils 12 and 13 to form the zinc film 14. Due to the zinc film 14, the barrier plating layer 15 formed subsequently is firmly bonded to the aluminum foils 12 and 13. Subsequently, the printed wiring board including the barrier plating layer 15 firmly bonded to the aluminum foils 12 and 13 is subjected to a conductive treatment to form the plating layer 17 in the through-hole TH. Accordingly, an aluminum-based printed wiring board including a highly reliable interlayer connection path can be obtained.

In other words, by subjecting the double-sided aluminum foil-clad substrate 10 in which the through-hole TH has been formed to a zincate treatment to form the zinc film 14 and then forming the barrier plating layer 15 on the zinc film 14 before performing a conductive treatment, the present embodiment enables an interlayer connection path to be formed by the conductive treatment and subsequent plating even when the double-sided aluminum foil-clad substrate 10 is used as a starting material.

As a comparative example of the present embodiment, conceivably, after subjecting the double-sided aluminum foil-clad substrate 10 in which the through-hole TH has been formed to a conductive treatment, a zincate treatment may be performed to form a plating layer (plated through-hole). However, since a strongly alkaline solution is used during the zincate treatment, there is a risk that the conductive carbon layer may peel off from the insulating base material exposed on the inner wall of the through-hole TH. In this case, the plating layer is not firmly bonded to the inner wall of the through-hole TH and reliability of the interlayer connection path declines.

Furthermore, in the case of the comparative example, when forming the plating layer by copper sulfate plating, there is a risk that the zinc film formed by the zincate treatment may be dissolved by sulfuric acid, thereby reducing a bond strength between the plating layer and the aluminum foils.

In contrast, the present embodiment is capable of avoiding such problems by subjecting the double-sided aluminum foil-clad substrate 10 in which the through-hole TH has been formed to a zincate treatment to form the zinc film 14 and then forming the barrier plating layer 15 on the zinc film 14 before performing a conductive treatment and forming a plated through-hole.

In addition, according to the present embodiment, since the through-hole TH can be formed by drilling or laser machining, a position and a size (diameter) of the through-hole TH can be adjusted with high precision.

Furthermore, in the present embodiment, since the wiring patterns WP1 and WP2 include aluminum foil, the weight of the printed wiring board can be reduced. In addition, since the wiring patterns WP1 and WP2 do not include the barrier plating layer 15 and the plating layer 17, the weight of the printed wiring board can be further reduced.

Note that the plating for forming the barrier plating layer 15 in step S14 is not limited to copper plating and may be plating of other metals. In other words, the barrier plating layer 15 may be constituted of a metal other than copper such as nickel (Ni), tin (Sn), chromium (Cr), zinc (Zn), cobalt (Co), or iron (Fe).

When using the printed wiring board, there is a risk that the aluminum in the wiring patterns WP1 and WP2 in contact with the plating layer 17 may be eluted by bimetallic corrosion (galvanic corrosion) attributable to a potential difference between different metals. For example, when the printed wiring board is applied to a battery, if an electrolyte comes into contact with portions where a copper plating layer and aluminum are in contact with each other, bimetallic corrosion occurs and causes the aluminum to elute. To prevent aluminum from eluting, the barrier plating layer 15 and/or the plating layer 17 are preferably formed using a metal of which standard electrode potential is relatively close to that of aluminum. For example, the barrier plating layer 15 and/or the plating layer 17 are constituted of nickel (Ni) or tin (Sn).

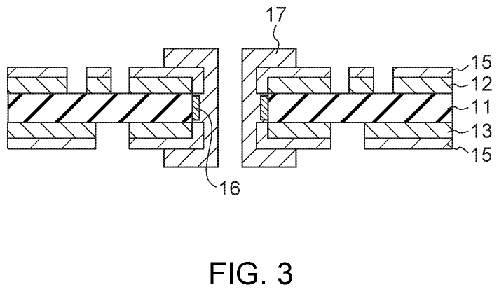

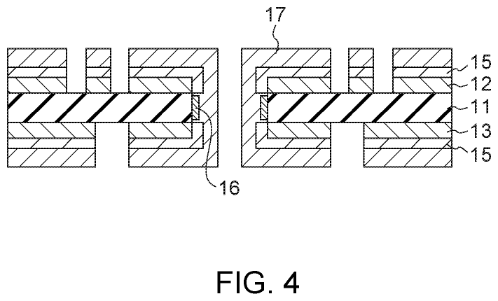

Next, Modifications 1 and 2 of the present embodiment will be described with reference to FIGS. 3 and 4, respectively. Since steps S11 to S15 are the same for both modifications, the description will begin with the steps that follow.

### First Modification

In the present modification, button plating is performed in step S16 to selectively form the plating layer 17 only in and around the through-hole TH. Subsequently, step S17 is omitted, and in step S18, as shown in FIG. 3, the aluminum foil 12 and/or the aluminum foil 13 that are not covered by the plating layer 17 but are covered by the barrier plating layer 15 are patterned. Accordingly, a wiring pattern with a laminated structure of the aluminum foil 12 and the barrier plating layer 15 (or the aluminum foil 13 and the barrier plating layer 15) is formed. Note that only one of the aluminum foil 12 and the aluminum foil 13 may be patterned.

According to the present modification, since the step of removing the barrier plating layer 15 after forming the plating layer 17 can be omitted, the method of manufacturing a printed wiring board can be simplified.

### Second Modification

In the present modification, as shown in FIG. 4, panel plating is performed in step S16 to form the plating layer 17 over the entire surface of the double-sided aluminum foil-clad substrate 10. Subsequently, step S17 is omitted, and in step S18, the aluminum foil 12 and/or the aluminum foil 13 that are covered by the plating layer 17 and the barrier plating layer 15 are patterned. Accordingly, a wiring pattern with a laminated structure of the aluminum foil 12, the barrier plating layer 15, and the plating layer 17 (the aluminum foil 13, the barrier plating layer 15, and the plating layer 17) is formed. Note that only one of the aluminum foil 12 and the aluminum foil 13 may be patterned.

According to the present modification, since the step of forming a mask using a dry film or the like when forming the plating layer 17 can be omitted, the method of manufacturing a printed wiring board can be simplified even further than in Modification 1.

### Embodiment 1

In the present embodiment, the double-sided aluminum foil-clad substrate 10 used was made by laminating single-sided aluminum foil-clad substrates with a 20 μm-thick adhesive layer (Ad). Each single-sided aluminum foil-clad substrate had a 50 μm-thick aluminum foil bonded to a 25 μm-thick polyimide (PI) film via a 10 μm-thick adhesive layer. An aluminum alloy or, more specifically, an aluminum alloy conforming to JIS 1N30 was used for the aluminum foil (Al). Three types of samples of through-holes (TH) having diameters of 150 μm, 200 μm, and 300 μm were prepared.

Samples in which the barrier plating layer 15 was formed by electrolytic copper plating and samples in which the barrier plating layer 15 was formed by electroless copper plating were prepared. A thickness of the barrier plating layer 15 was set to 3 μm. The plating layer 17 was formed 15 μm-thick by copper sulfate plating.

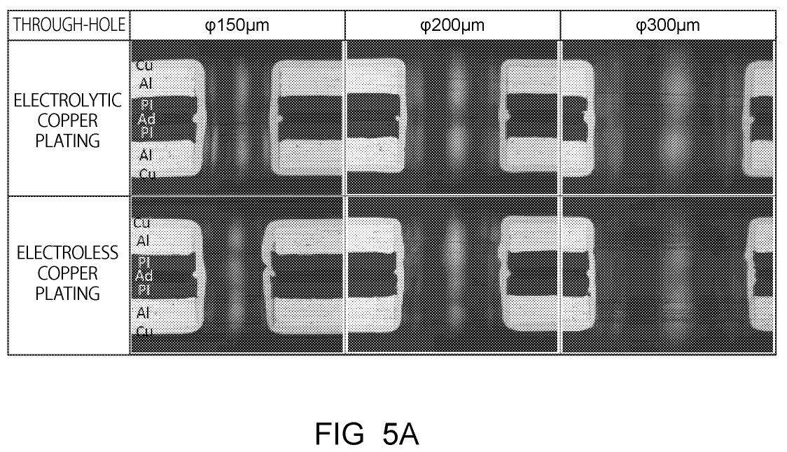

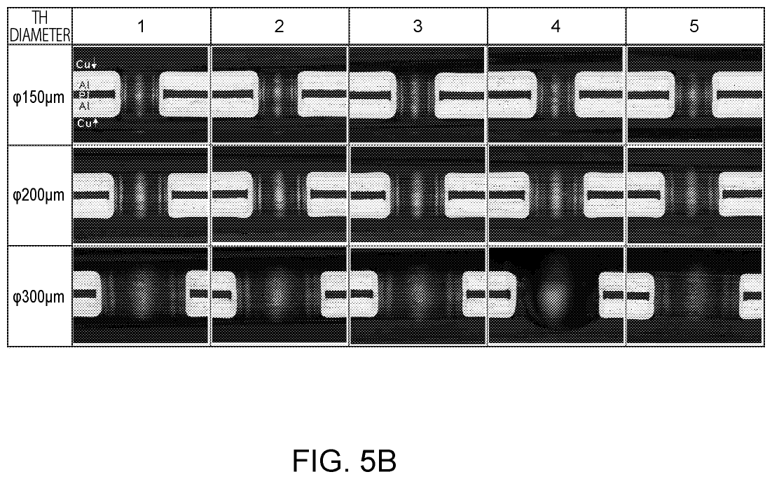

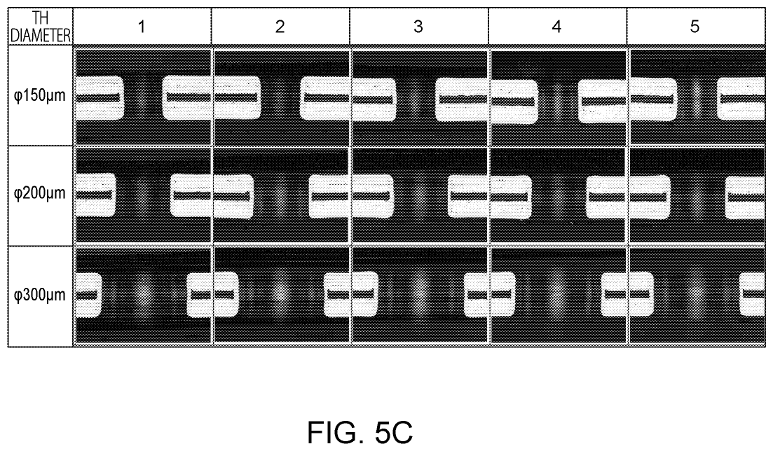

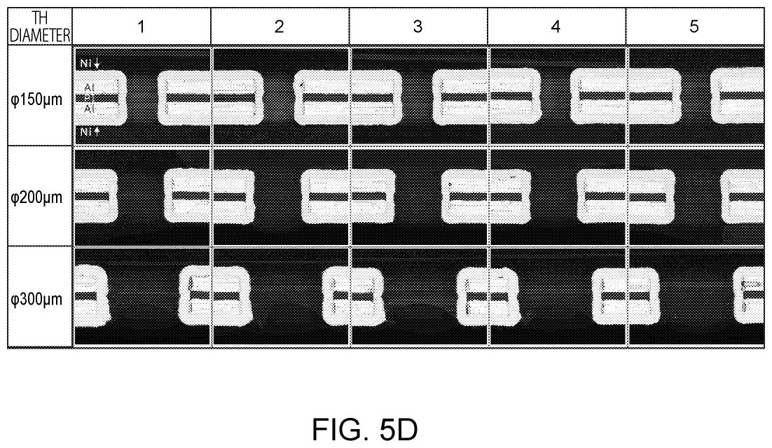

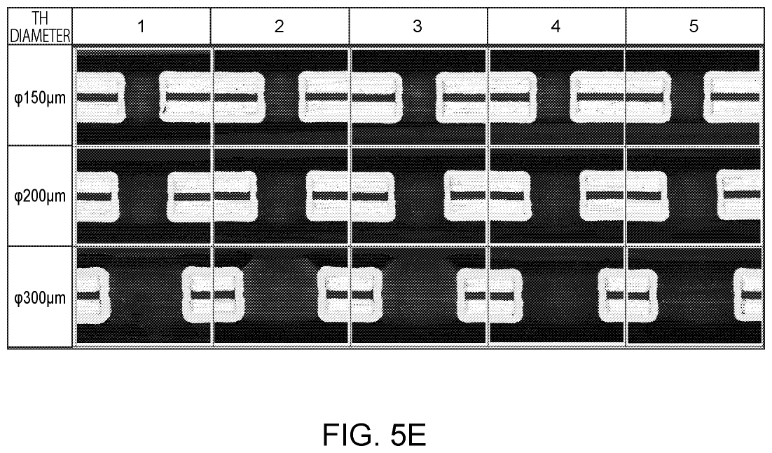

FIG. 5A shows an example of photographs of a cross section of a printed wiring board actually manufactured. FIG. 5A shows that, regardless of the plating method used to form the barrier plating layer 15 (electrolytic copper plating or electroless copper plating) or the diameter of the through-hole TH, the copper plating (plating layer 17) is formed on the aluminum foils and the inner wall of the through-hole without any gaps (without voids) and with high adhesion strength.

### Embodiment 2

In Embodiment 2, using a double-sided aluminum foil-clad substrate different from that in Embodiment 1, an interlayer connection path was formed by barrier copper plating and electrolytic copper plating.

As the double-sided aluminum foil-clad substrate 10, a double-sided aluminum foil-clad substrate in which a 50 μm-thick aluminum foil was provided to both sides of a 25 μm-thick polyimide film was used. An aluminum alloy or, more specifically, an aluminum alloy conforming to JIS 1N30 was used for the aluminum foil (Al). Three types of through-holes TH having diameters of 150 μm, 200 μm, and 300 μm were prepared.

In the present embodiment, the 3 μm-thick barrier plating layer 15 was formed by electrolytic copper plating and the 15 μm-thick plating layer 17 was formed by copper sulfate plating. FIG. 5B shows an example of photographs of a cross section of a manufactured printed wiring board. Cross sections of five randomly selected through-holes from among the large number of through-holes formed in a single FPC were examined. The numerals 1 to 5 in the drawing are sequential numbers of the through holes of which the cross sections were photographed.

FIG. 5B shows that, regardless of the diameter of the through-hole TH, the copper plating (plating layer 17) is formed on the aluminum foils and the inner wall of the through-hole without any gaps and with high adhesion strength for all through-holes TH.

In addition, a hot oil test was conducted to evaluate resistance of the interlayer connection path to thermal shock. The hot oil test is a thermal shock test that involves repeatedly immersing a printed wiring board in high-temperature oil and then cooling it to room temperature. In this case, a printed wiring board with plated-through holes formed by copper plating was subjected to 100 cycles involving a 20-second immersion in oil at 260 °C followed by a 20-second cooling period at room temperature of 20 °C. FIG. 5C shows cross sections of plated through-holes in the printed wiring board after the hot oil test. FIG. 5C shows that, even after the hot oil test, no cracks have developed in the plating layer and connection reliability is ensured.

### Embodiment 3

In Embodiment 3, using the same double-sided aluminum foil-clad substrate as in Embodiment 2, an interlayer connection path was formed by barrier nickel plating and electrolytic nickel plating.

In the present embodiment, the 3 μm-thick barrier plating layer 15 was formed by electrolytic nickel plating and the 20 μm to 25 μm-thick plating layer 17 was formed by electrolytic nickel plating. FIG. 5D shows an example of photographs of a cross section of a manufactured printed wiring board. Cross sections of five randomly selected through-holes from among the large number of through-holes formed in a single FPC were examined. The numerals 1 to 5 in the drawing are sequential numbers of the through holes of which the cross sections were photographed.

FIG. 5D shows that, regardless of the diameter of the through-hole TH, the nickel plating (plating layer 17) is formed on the aluminum foils and the inner wall of the through-hole without any gaps and with high adhesion strength for all through-holes TH. While it should be noted that black foreign matter (carbon residue) is visible between the barrier plating layer and the plating layer, the black foreign matter is conceivably due to the use of an etching solution designed for copper in the soft etching treatment.

In addition, a hot oil test was conducted in a similar manner to Embodiment 2 so as to evaluate resistance of the interlayer connection path to thermal shock. In this case, a printed wiring board with plated-through holes formed by nickel plating was subjected to 100 cycles involving a 20-second immersion in oil at 260 °C followed by a 20-second cooling period at room temperature of 20 °C. FIG. 5E shows cross sections of plated through-holes in the printed wiring board after the hot oil test. FIG. 5E shows that, even after the hot oil test, no cracks have developed in the plating layer and connection reliability is ensured.

### Second Embodiment

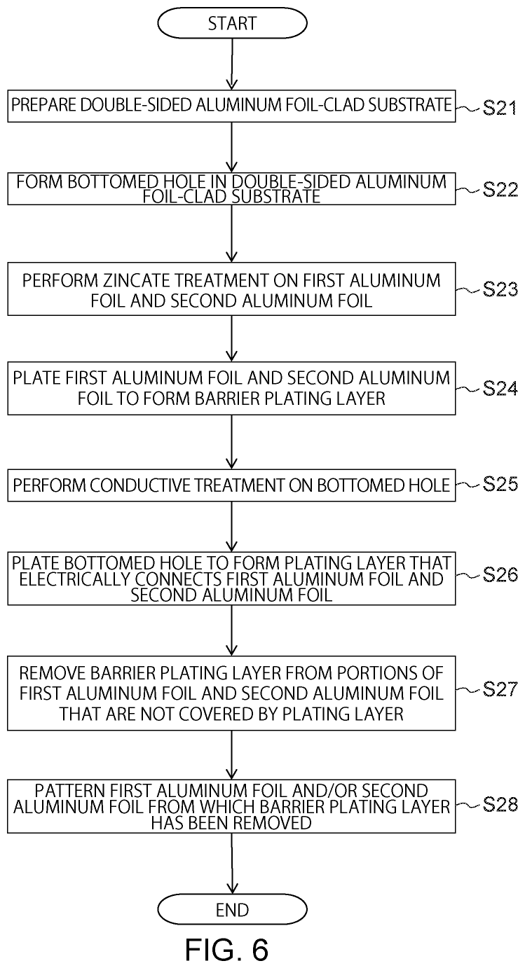

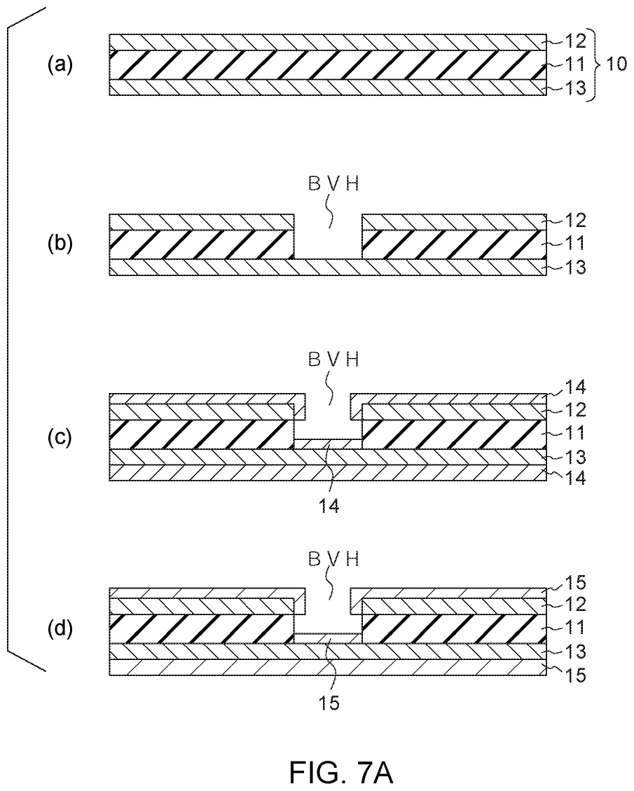

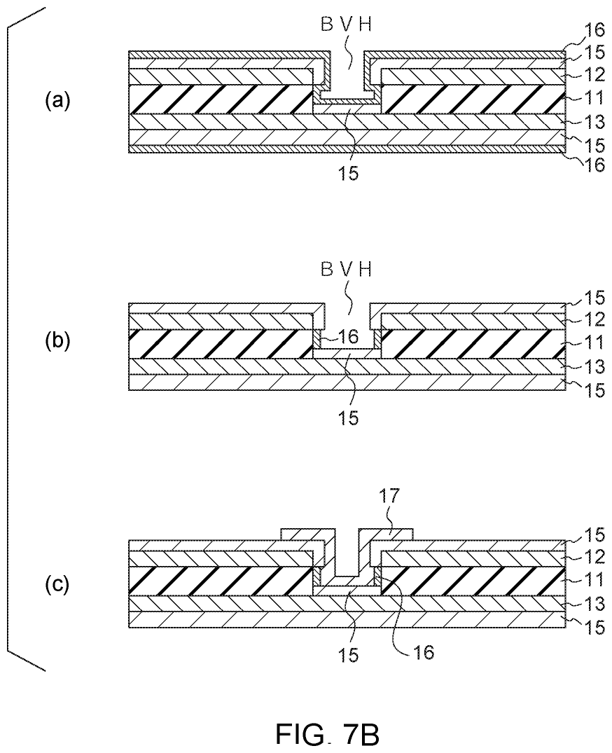

Next, a method of manufacturing a printed wiring board according to a second embodiment will be described with reference to the flow chart in FIG. 6 and the process sectional views in FIGS. 7A and 7B. One difference from the first embodiment is that the interlayer connection path is formed in a bottomed hole instead of a through hole. Hereinafter, the second embodiment will be described with a focus on differences from the first embodiment.

Step S21: As shown in FIG. 7A (a), the double-sided aluminum foil-clad substrate 10 is prepared. Since the present step is the same as step S11 described in the first embodiment, a detailed description will be omitted.

Step S22: As shown in FIG. 7A (b), a bottomed hole BVH is formed in the double-sided aluminum foil-clad substrate 10. The aluminum foil 13 is exposed in a bottom portion of the bottomed hole BVH. The bottomed hole BVH is formed by laser machining using a CO₂ laser or the like. Note that after forming the bottomed hole BVH, desmearing that removes smear may be performed.

Step S23: A zincate treatment is performed on the aluminum foil 12 and the aluminum foil 13. Due to the zincate treatment in the present step, as shown in FIG. 7A (c), an oxide film on the surfaces of the aluminum foils 12 and 13 is removed and the zinc film 14 is formed. The zinc film 14 is formed on the surfaces of the aluminum foils 12 and 13.

Step S24: As shown in FIG. 7A (d), the aluminum foils 12 and 13 having undergone the zincate treatment are plated to form a barrier plating layer 15. The barrier plating layer 15 is formed on the surfaces of the aluminum foils 12 and 13. The plating in the present step is, for example, copper plating, in which case the copper plating may be either electrolytic copper plating or electroless copper plating. Although not illustrated in FIG. 7A (d), the zinc film 14 thinly remains between the aluminum foil 12 and the barrier plating layer 15 (between the aluminum foil 13 and the barrier plating layer 15).

Step S25: A conductive treatment is performed on the bottomed hole BVH. The conductive treatment of the present step is similar to the conductive treatment performed on through-holes formed in conventional double-sided copper clad laminates. Specifically, first, as shown in FIG. 7B (a), by immersing the double-sided aluminum foil-clad substrate 10 in a suspension in which carbon particles (carbon black powder, fine graphite) are uniformly dispersed in a solvent, the conductive carbon layer 16 is formed over the entire surface of the double-sided aluminum foil-clad substrate 10. The conductive carbon layer 16 is formed by physical adsorption of carbon particles onto the surface of the double-sided aluminum foil-clad substrate 10 and has a thickness ranging from several nanometers to several tens of nanometers. Next, as shown in FIG. 7B (b), the conductive carbon layer 16 is removed, with the exception of the conductive carbon layer 16 on the insulating base material exposed on an inner wall of the bottomed hole BVH.

Step S26: As shown in FIG. 7B (c), the bottomed hole BVH having undergone the conductive treatment is plated to form the plating layer 17. The plating layer 17 serves as an interlayer connection path that electrically connects the aluminum foil 12 and the aluminum foil 13. In the present example, the plating layer 17 is selectively formed only in and around the bottomed hole BVH by button plating.

Step S27: Although not illustrated, the barrier plating layer 15 in portions of the aluminum foil 12 and the aluminum foil 13 that are not covered by the plating layer 17 is removed by etching in a similar manner to the first embodiment.

Step S28: Although not illustrated, the aluminum foil 12 and/or the aluminum foil 13 from which the barrier plating layer 15 has been removed is patterned.

Note that in the second embodiment, wiring patterns may be formed by the methods described in Modification 1 or 2 of the first embodiment.

According to the method of manufacturing a printed wiring board of the second embodiment, a printed wiring board is obtained in which wiring patterns provided on both sides of the insulating base material and including an aluminum foil are electrically connected to one another via interlayer connection paths formed in bottomed holes.

Note that the plating for forming the barrier plating layer 15 in step S24 is not limited to copper plating and may be plating of other metals in a similar manner to the first embodiment. In other words, even in the second embodiment, the barrier plating layer 15 may be constituted of a metal other than copper such as nickel (Ni), tin (Sn), chromium (Cr), zinc (Zn), cobalt (Co), or iron (Fe).

### Printed Wiring Board

The printed wiring board manufactured by the method of manufacturing a printed wiring board according to the first and second embodiments described above is as follows.

The printed wiring board includes the insulating base material 11, the wiring pattern WP1 provided on an upper side of the insulating base material 11, the wiring pattern WP1 including the aluminum foil 12 between the insulating base material 11 and the wiring pattern WP1, the wiring pattern WP2 provided on a lower side of the insulating base material 11, the wiring pattern WP2 including the aluminum foil 13 between the insulating base material 11 and the wiring pattern WP2, and the plating layer 17 formed on an inner wall of through-holes of the insulating base material 11 to electrically connect the wiring pattern WP1 and the wiring pattern WP2. In addition, the barrier plating layer 15 is provided between the plating layer 17 and the aluminum foils 12 and 13. Furthermore, as a signature that a zincate treatment has been performed, the zinc film 14 is present between the barrier plating layer 15 and the aluminum foils 12 and 13. In other words, the zinc film 14 is present as a substrate for the barrier plating layer 15.

Specifically, in the printed wiring board manufactured by the method of manufacturing a printed wiring board according to the first embodiment and modifications thereof, the barrier plating layer 15 is provided between the plating layer 17 and the aluminum foils 12 and 13 at least in the through-hole TH and a vicinity thereof. In addition, the zinc film 14 is present between the barrier plating layer 15 and the aluminum foils 12 and 13.

In the printed wiring board manufactured by the method of manufacturing a printed wiring board according to the second embodiment, the barrier plating layer 15 is provided between the plating layer 17 and the aluminum foil 12 and the zinc film 14 is present between the barrier plating layer 15 and the aluminum foil 12 at least in the bottomed hole BVH and a vicinity thereof. In addition, the barrier plating layer 15 is provided between the plating layer 17 and the aluminum foil 13 exposed in a bottom portion of the bottomed hole BVH and the zinc film 14 is present between the barrier plating layer 15 and the aluminum foil 13.

While additional advantageous effects and various modifications may be made by those skilled in the art based on the description given above, aspects of the present invention are not limited to the individual embodiments presented above. Constituent elements over different embodiments may be appropriately combined. Various additions, modifications, and partial deletions can be made without departing from the conceptual thoughts and the gist of the present invention that can be derived from the contents defined in the claims and equivalents thereof.

### REFERENCE SIGNS LIST

1 printed wiring board
10 double-sided aluminum foil-clad substrate
11 insulating base material
12, 13 aluminum foil
14 zinc film
15 barrier plating layer
16 conductive carbon layer
17 plating layer
BVH bottomed hole
TH through-hole
WP1, WP2 wiring pattern

What is claimed is:

1. A method of manufacturing a printed wiring board, comprising:
preparing a double-sided aluminum foil-clad substrate including an insulating base material, a first aluminum foil provided on a first main side of the insulating base material, and a second aluminum foil provided on a second main side of the insulating base material;
forming a through-hole that penetrates the double-sided aluminum foil-clad substrate in a thickness direction or a bottomed hole with a bottom portion in which the second aluminum foil is exposed;
performing a zincate treatment on the first aluminum foil and the second aluminum foil;
plating the first aluminum foil and the second aluminum foil having undergone the zincate treatment to form a barrier plating layer;
after forming the barrier plating layer, performing a conductive treatment on the through-hole or the bottomed hole; and
plating the through-hole or the bottomed hole having undergone the conductive treatment to form a plating layer that electrically connects the first aluminum foil and the second aluminum foil.

2. The method of manufacturing a printed wiring board according to claim 1, wherein the barrier plating layer and/or the plating layer are made of nickel or tin.

3. The method of manufacturing a printed wiring board according to claim 1, wherein the barrier plating layer and/or the plating layer are made of copper.

4. The method of manufacturing a printed wiring board according to claim 1, wherein the plating is button plating, and the method further comprises:
removing the barrier plating layer from portions of the first aluminum foil and the second aluminum foil that are not covered by the plating layer; and
patterning the first aluminum foil and/or the second aluminum foil from which the barrier plating layer has been removed.

5. The method of manufacturing a printed wiring board according to claim 1, wherein the plating is button plating, and the method further comprises:
patterning the first aluminum foil and/or the second aluminum foil that are not covered by the plating layer but are covered by the barrier plating layer.

6. The method of manufacturing a printed wiring board according to claim 1, wherein the plating is panel plating, and the method further comprises:
patterning the first aluminum foil and/or the second aluminum foil that are covered by the plating layer and the barrier plating layer.

7. The method of manufacturing a printed wiring board according to claim 1, wherein the plating is electrolytic plating or electroless plating.

8. The method of manufacturing a printed wiring board according to claim 1, wherein the first and second aluminum foils are made of pure aluminum or an aluminum alloy.

9. The method of manufacturing a printed wiring board according to claim 1, wherein the double-sided aluminum foil-clad substrate is flexible.

10. A printed wiring board, comprising:
an insulating base material;
a first wiring pattern provided on an upper side of the insulating base material, the first wiring pattern including a first aluminum foil between the insulating base material and the first wiring pattern;
a second wiring pattern provided on a lower side of the insulating base material, the second wiring pattern including a second aluminum foil between the insulating base material and the second wiring pattern; and
a plating layer formed on an inner wall of a through-hole of the insulating base material to electrically connect the first wiring pattern and the second wiring pattern, wherein
a barrier plating layer is provided between the plating layer and the first aluminum foil and between the plating layer and the second aluminum foil, and a zinc film is present between the barrier plating layer and the first aluminum foil and between the barrier plating layer and the second aluminum foil.

11. The printed wiring board according to claim 10, wherein the barrier plating layer and/or the plating layer are made of nickel or tin.

12. The printed wiring board according to claim 10, wherein the barrier plating layer and/or the plating layer are made of copper.

13. The printed wiring board according to claim 10, wherein the first and second aluminum foils are made of pure aluminum or an aluminum alloy.

14. The printed wiring board according to claim 10, wherein the insulating base material is flexible.
